(19) United States
(12) Patent Application Publication
(10) Pub. No.: US 2002/0043727 A1
(43) Pub. Date: Apr. 18, 2002

(54) Bonding pad structure

(76) Inventor: Hsiao-Che Wu, Taoyuan Hsien (TW)

Correspondence Address: J.C. Patents, Inc., 4 Venture, Suite 250, Irvine, CA, 92618, US

(21) Appl. No.: 09/777,248

(22) Filed: Feb. 5, 2001

(30) Foreign Application Priority Data
Oct. 13, 2000 (TW) 89121415

(51) Int. Cl. H01L 23/48

(52) U.S. Cl. 257/786

(57) ABSTRACT

A bonding pad structure with a bonding pad with a circular shape or an elliptical shape. The circular or the elliptical bonding pad structure does not have any sharp angularity. It improves the stress concentration problem which results from the abrupt shrinkage of the cross section of the protective layer. The circular or the elliptical shape of the bonding pad structure can also prevent the abrupt shrinkage of the cross section of the protective layer due to the gradual change of angularity. Therefore, this kind of shape can disperse the stress and prevent the abruption on the protective layer after the bonding wire and packaging produces.

### BACKGROUND OF THE INVENTION

1. Field of Invention

The present invention relates to a bonding pad structure. More particularly, this invention relates to a bonding pad structure in which the bonding pad is with a sharp-corner-prevented shape, such as a circular shape or an elliptical shape.

2. Description of Related Art

In a pre-stage semiconductor process, there are five photo-mask procedures respectively used for defining active areas, gate structures, contact structures between metal layers and source/drain regions, patterns of multiple metal interconnects, and bonding pads. Owing to requirements of higher integration of semiconductor devices and higher speed of functions or data processing, more and more signal connecting points are required and increased significantly. As the number of the signal connecting points is increased, bonding pads for the respective signal connecting points are also significantly increased. After the bonding pads being formed, in follow-up is a process of package for the integrated circuits (ICs). In particularly, electrically coupling the semiconductor device and the bonding pads and connecting gold wires with lead-frames are so-called bonding wire. The gold wire is in a range of about 20-50 μm. The purpose of bonging wire is coupling the bonding pads of the semiconductor device with the internal lead-leg of the lead-frame, by which signals of the semiconductor device can be transmitted to an external device.

In the process of bonding wire, the bonding pad of the semiconductor device acts as a first bonding point, and the internal lead-leg of the lead-frame acts as a second bonging point. Then, an end of the gold wire is heated and melted into a small ball, and the portion of the small ball is compressed on the bonding pad by way of ultra-sonic waves. The gold wire is bonded on the internal lead-leg of the lead-fram after routing along a predetermined path, and then is broken away.

The operation of bonding wire repeats again and again until all connections are completed. During the bonding wire process, the ultra-sonic waves are introduced for compressing the small ball upon the bonding pad, a protective layer or a dielectric layer around the bonding pads is easily cracked by the stress caused by the ultra-sonic waves. After the process of bonding wire, the semiconductor device is packaged, and differences of coefficients of thermal expansion (CTE) between the epoxy resin and the protective layer may cause the protective layer or the dielectric layer to crack at a stress concentration point.

Referring to FIG. 1a through FIG. 1f, there are top and cross-sectional views of a conventional bonding pad with a square shape. FIG. 1a through FIG. 1f show signal connecting points 102 located on a semiconductor device 100 are directly or through the varied types of plugs 104 electrically coupled to a bonding pad 106. The plugs 104 in a dielectric layer 105, as shown in FIG. 1a to FIG. 1e, are designed for preventing noises caused by an antenna effect.

After connection of each bonding pad 106 and the respective signal connecting point 102, a protective layer 108 is formed over the semiconductor device 100, and is then defined by a photolithography process and an following etching process to expose the bonding pad 106. Therefore, the bonding pads 106 in the semiconductor device 100 are isolated from each other by the protective layer 108. Owing to the square shapes of the bonding pads 106 in the conventional device, it easily causes the stress between the bonding pad 106 and the protective layer 108 to concentrate on the corner of bonding pad 106 due to the abrupt shrinkage of the cross section of said protective layer 108. A cross-sectional area of the protective layer 108 beside and near the bonding pad 106 is much larger than a cross-sectional area of the protective layer 108 between a central portion of two adjacent bonding pads 106. The difference of the cross-sectional areas of the protective layer 108 is apparently and significantly reduced from the corner of the bonding pad 106 to the central portion of the two adjacent bonding pads 106. That is the reason why the stress is concentrated on the corner of the bonding pad 106.

The square-shaped bonding pad 106 will cause the problem of the stress between protective layer 108 and bonding pad 106 to concentrate on the corner of said bonding pad 106. In the later bonding wire process, the small gold ball is compressed on the bonding pad 106 through the ultra-sonic waves, however, the ultra-sonic wave can easily result in the abruption of protective layer 108 and the dielectric layer 105. Besides, after packaging procedure, protective layer 108 or dielectric layer 105 will abrupt on the stress concentration point due to the difference of the coefficient of thermal expansion between the epoxy resin and the wafer.

The square-shaped design of bonding pad can cause the stress to concentrate on the corner of the bonding pad, and the abruption of protective layer or dielectric layer will happen in the following bonding wire and packaging procedures.

### SUMMARY OF THE INVENTION

The invention provides a bonding pad with a circular or an elliptical structure. The circular or the elliptical bonding pad structure does not have any sharp angularity. It improves the stress concentration problem which results from the abrupt shrinkage of the cross section of the protective layer.

As embodied and broadly described herein, the invention provides a bonding pad structure with the circular or the elliptical structure. The circular or the elliptical shape of the bonding pad structure can prevent the abrupt shrinkage of the cross section of the protective layer due to the gradual change of angularity. Therefore, this kind of shape can disperse the stress and prevent the abruption on the protective layer after the bonding wire and packaging produces.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings, FIG. 1a through FIG. 1f are the top and cross-sectional views of a conventional semiconductor device with square-shaped bonding pads;

FIG. 2 is a stress concentration factor diagram, that illustrates the ratio (radius to small distance, r/d) versus the stress concentration factor K, and the small picture on the diagram shows the same material at different parts of the cross-sectional areas (D → d).

FIG. 3a through FIG. 3f are the top and cross-sectional views of a semiconductor device with circular-shaped bonding pads according to a preferred embodiment of the invention.

FIG. 4a through FIG. 4f are the top and cross-sectional views of a semiconductor device with elliptical-shaped bonding pads according to another preferred embodiment of the invention.

### DESCRIPTION OF THE PREFERRED EMBODIMENTS

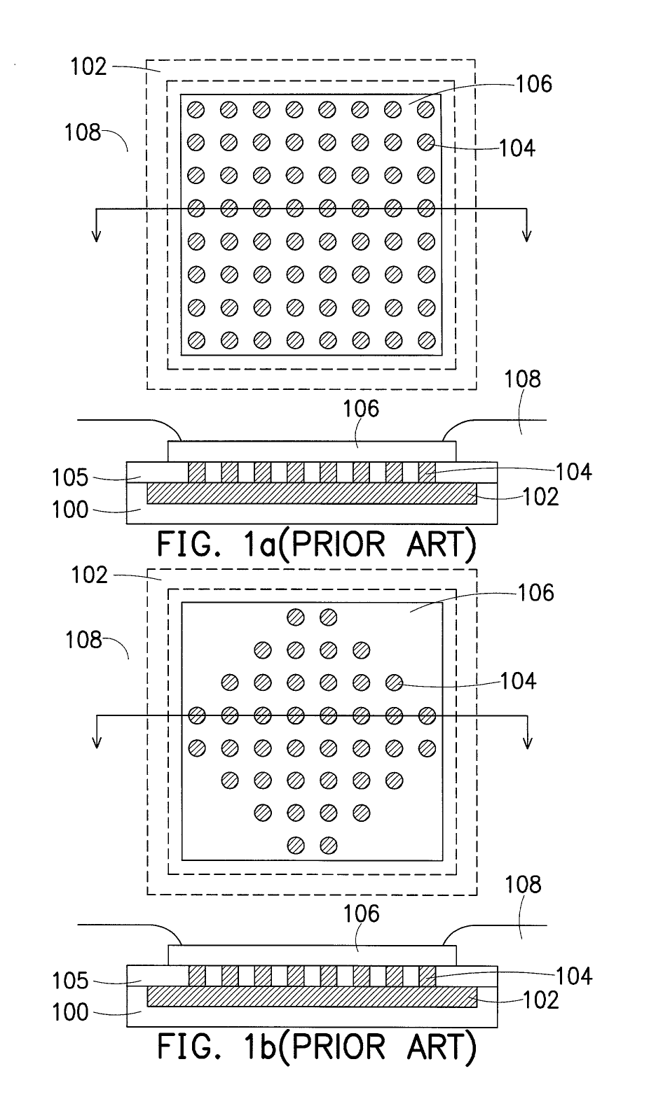

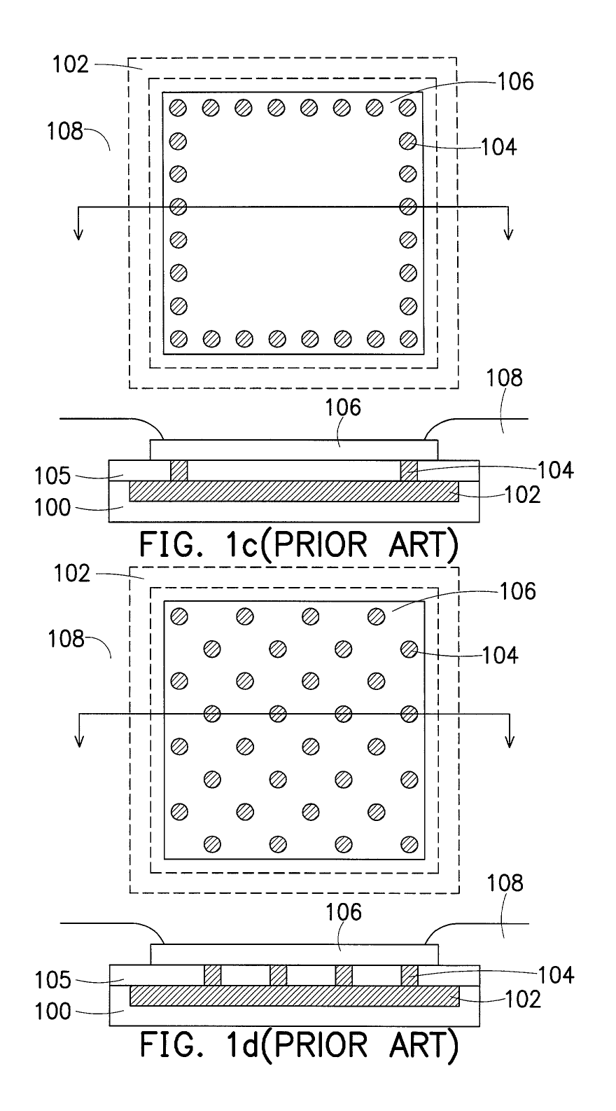

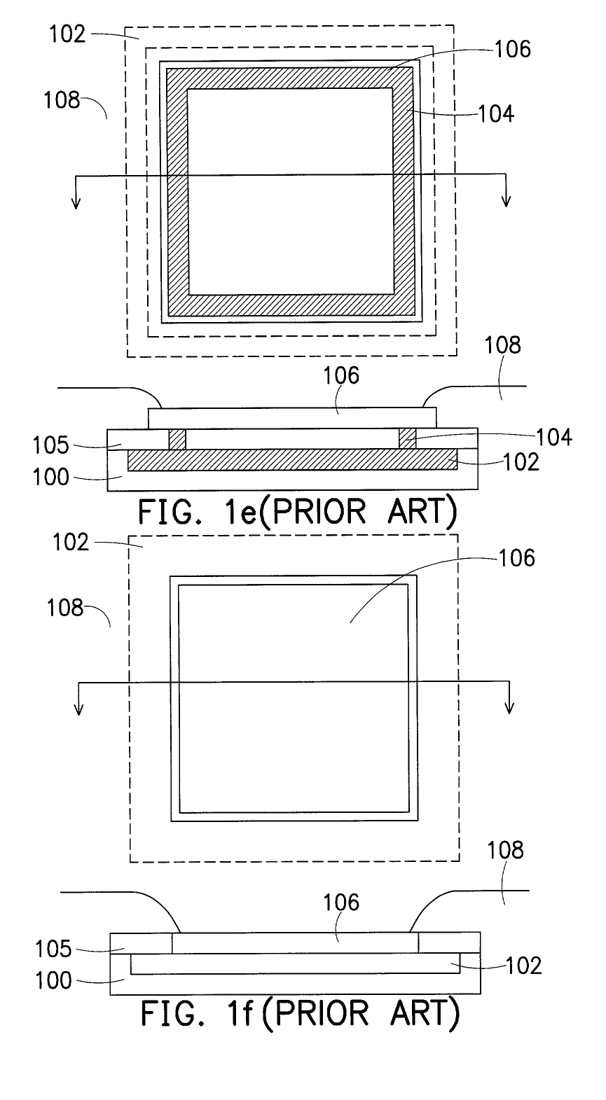

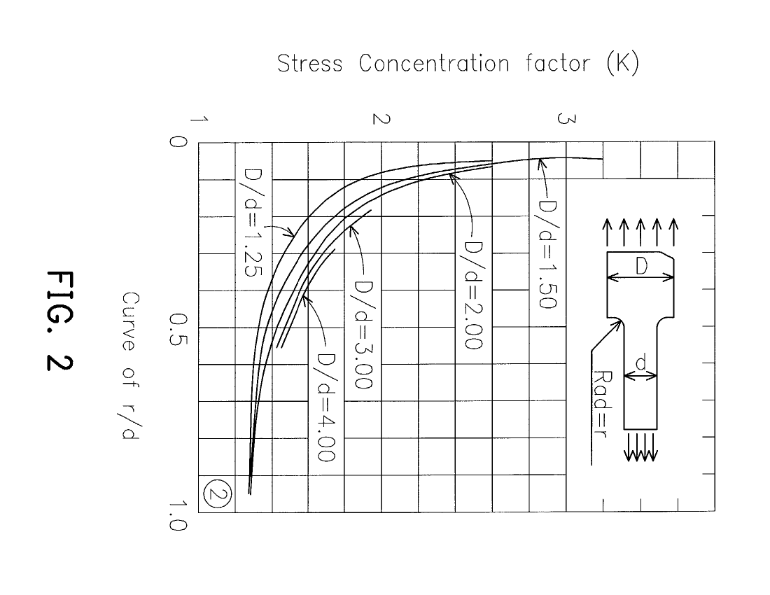

At first, referring to FIG. 2, showing a relationship between a stress concentration factor K and a curve ratio (r/d) under a condition of different cross-sectional areas (D → d) in a same material. D is a bigger width of the material in the cross-section, d is the smaller width of the material in the cross section, and r/d is the curve ratio of areas between the area with the width D of the material and the area with the width d of the material in cross-section. There are four different values showing abrupt shrinkages of the cross-sectional area in the material, which are D/d=1.50, D/d=2.00, D/d=3.00 and D/d=4.00. The stress concentration factor K non-linearly decreases as the curvature (radius to small distance, r/d) increases. Accordingly, in an interface between a portion of the material with a bigger cross-sectional area and a portion of the material with a smaller cross-sectional area, if a better and bigger curve ratio (r/d) is provided, the abrupt shrinkages of the cross-sectional area are improved and reduced. That is, the stress concentration factor K is reduced, in order to disperse the strength of the stress.

The conventional structure of the bonding pad 106 and the protective layer 108, as shown in FIGS. 1a-1f, exists the stress concentration problem at the intersection of a wider cross-sectional area and a narrower cross-sectional area in the protective layer 108. Referring to FIG. 2, according to the bonding pad 106 with a square shape, the (r/d) ratio of the corner is approximately to zero, it has a maximum stress in the packaging process. The maximum stress may cause a problem of crack in the following process.

Therefore, this invention provides a bonding pad with a circular shape or an elliptical shape, which increases a curve ratio (r/d) in the intersection of a wider cross-sectional area and a narrower cross-sectional area. That means that a smaller stress concentration factor K is provided by improving and increasing the curve ratio (r/d).

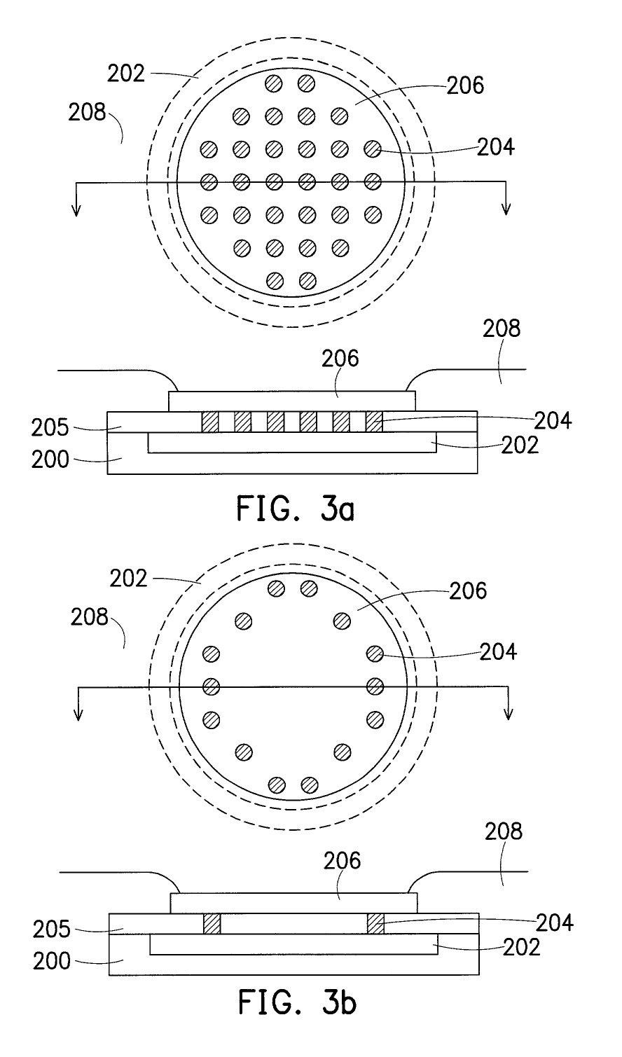

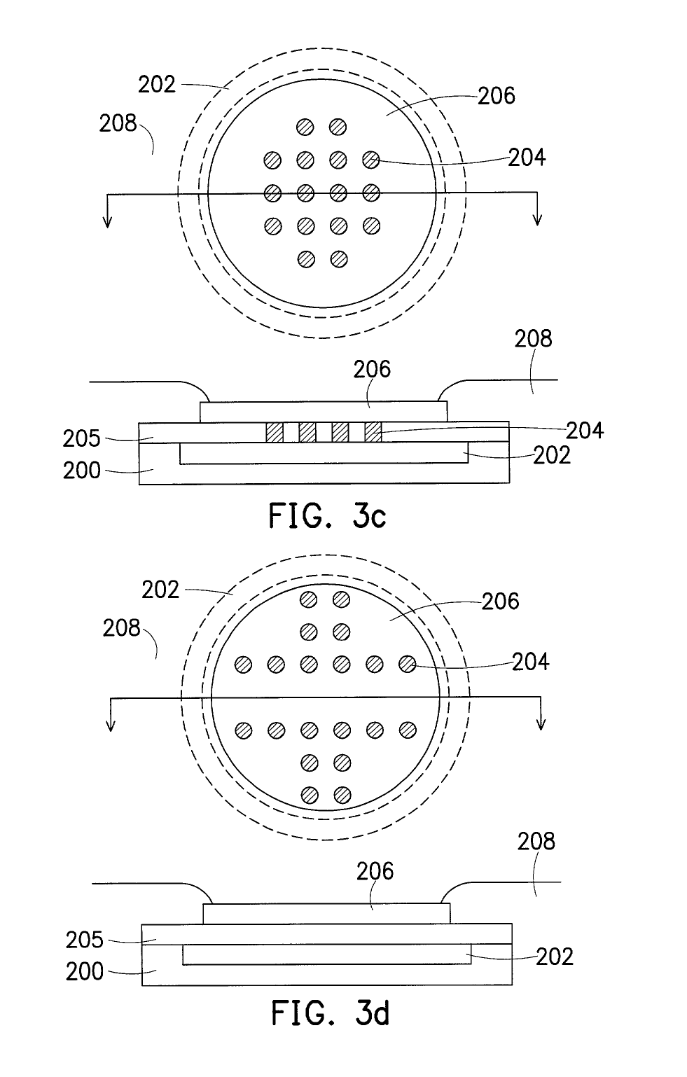

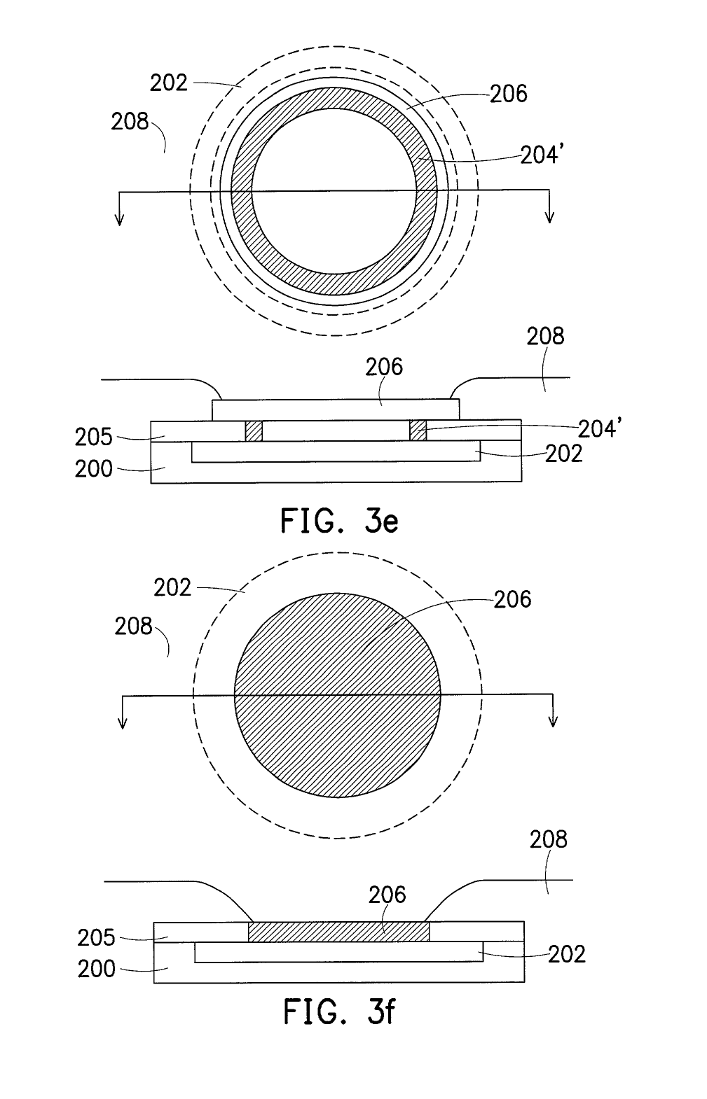

Referring to FIG. 3a through FIG. 3f. FIG. 3a through FIG. 3f are the top and cross-sectional views of a semiconductor device 200 with circular-shaped bonding pads according to a preferred embodiment of the invention. The top views of FIG. 3a through FIG. 3f illustrate a signal connecting point 202 on a semiconductor device 200 is electrically coupled to a circular-shaped bonding pad 206, either through plugs 204 with different arrangements, round-shaped conductor 204′ in a dielectric layer 205, or directly.

Referring to FIG. 3a, the plugs 204 of the dielectric layer 205 are evenly distributed like a matrix under the coverage of the circular-shaped bonding pad 206. Referring to FIG. 3b, the plugs 204 are distributed as a circular array under the board of circular-shaped bonding pad 206. Referring to FIG. 3c, the plugs 204 are distributed under the center portion of the circular-shaped bonding pad 206. Referring to FIG. 3d, the plugs 204 are distributed as a cross-shape under the circular-shaped bonding pad 206.

Referring to FIG. 3e, the connecting signal point 202 and the circular-shaped bonding pad 206 are coupled to each other by the round-shaped conductor 204′. Referring to FIG. 3f, the connecting signal point 202 directly connects to the circular-shaped bonding pad 206. The forming method of the plugs 204 and the round-shape conductor 204′ is to form the dielectric layer 205 over the signal connecting point 202, then form plural holes in the dielectric layer 205 by lithography and etch processes, and fill the conductive material into the plural holes to form the plug 204 and round-shape conductor 204′. In the FIG. 3a through FIG. 3e, the effects of the plug 204 and the round-shaped conductor 204′ are similar to those of the conventional design, which are both designed for avoiding the noise caused by the antenna effect.

After connecting each of the bonding pads 206 to the respective signal connecting point 202, a protective layer 208 is formed over the semiconductor device 200. The protective layer 208 is then performed by lithography and etching processes to expose the circular-shaped bonding pads 206. Therefore, the circular-shaped bonding pads 206 are isolated from each other by the protective layer 208. The material of the protective layer 208 is, for example, silicon nitride or silicon dioxide. The material of the circular-shaped bonding pad 206 is, for example, Aluminum (Al).

Referring to FIG. 3a through FIG. 3f, the bonding pads 206 are circular-shaped and do not have sharp corners. The design can prevent the abrupt shrinkage of cross sections of the protective layer 208 due to the gradual change of angularity. Therefore the stress can be equally distributed around the circular-shaped bonding pads 206 and the protective layer 208.

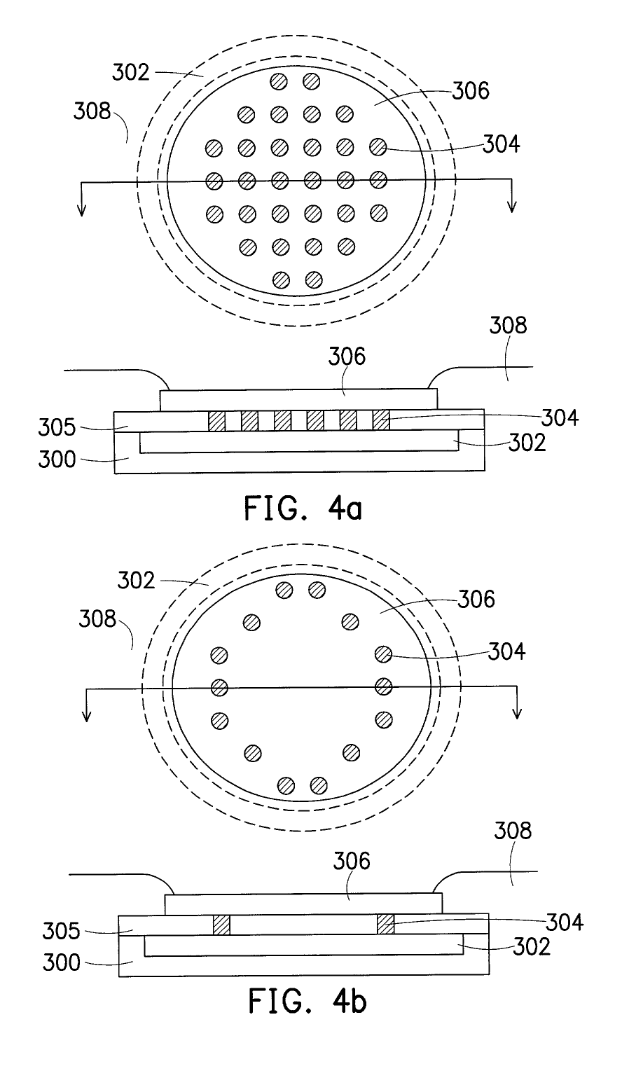

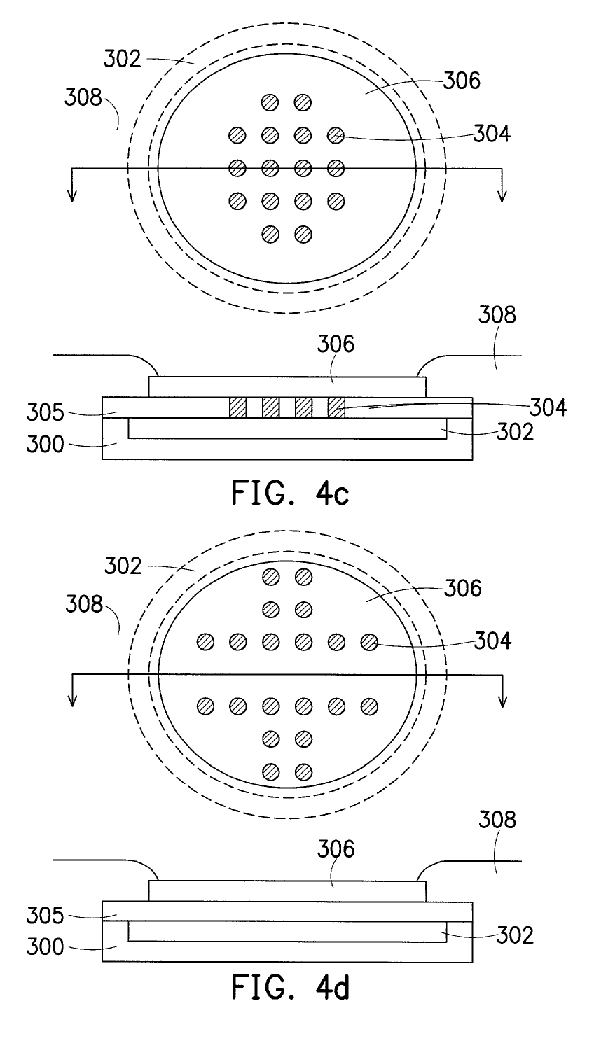

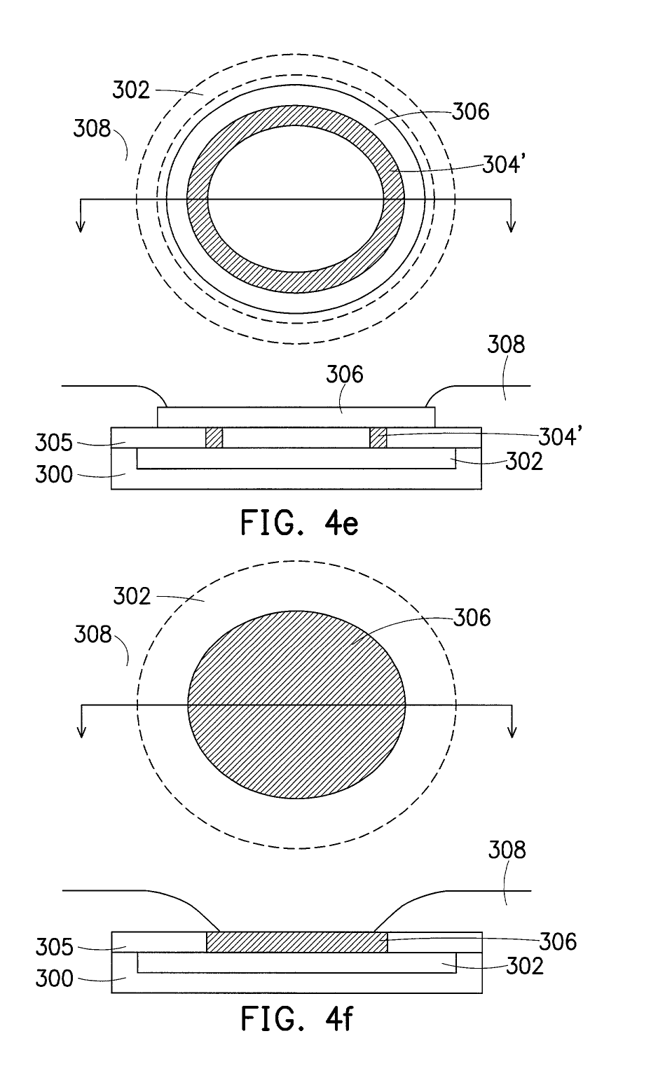

Referring to FIG. 4a through FIG. 4f, there are the top and cross-sectional views of a semiconductor device having a bonding pad with an elliptical shape. The structures in FIG. 4a to FIG. 4f are respectively similar with the structures in FIG. 3a to FIG. 3f. A signal connecting point 302 on a semiconductor device 300 is electrically coupled to a elliptical-shaped bonding pad 306, either through plugs 304 with different arrangements, round-shaped conductor 304′ in a dielectric layer 305, or directly. Both the plug 304 and the round shape conductor 304′ are designed to avoid noises caused by an antenna effect. The distribution of the plugs 304 and the round-shaped conductor 304′ are similar with the structure shown in FIG. 3a through FIG. 3f. The elliptical-shaped bonding pads 306 are isolated from each other by a protective layer 308 of dielectric material.

In the embodiment of FIG. 4a to FIG. 4f, the bonding pads 306 are with elliptical shapes, which mean that there are no sharp corners. Therefore, the design can prevent abrupt shrinkage of cross sections of the protective layer 308 due to the gradual change of angularity. Therefore the stress can be equally distributed around the elliptical-shaped bonding pads 306 and the protective layer 308.

In the above-mentioned embodiments, the bonding pads 206 or 306 are respectively designed to be with circular or elliptical shapes. The stress is well and evenly distributed between the bonding pads and the protective layer. The problem of over concentration of the stress is avoided. Crack problems while performing ultra-sonic waves for vibrating and compressing the gold wire on the bonding pads are avoided and prevented. In the same condition, owing to the well-distributed stress between the bonding pads and the protective layer, after packaging procedure, crack problems will not occur upon the protective layer 208 or the protective layer 308 by the difference of the coefficient of thermal expansion between the epoxy resin and the wafer.

Accordingly, some significant improvements are introduced in the invention:

1. This invention provides a structure of a bonding pad with a sharp-corner-prevented shape for a semiconductor device. For example, as disclosed in the two embodiments, a structure of a circular shape or an elliptical shape is provided for the bonding pad. It can disperse the stress between the protective layer and the bonding pad. It can prevent the stress overly concentrating in some points. That is, crack problems will not occur because the over concentration of stress is avoided.

2. The specific structure of the bonding pad with a sharp-corner-prevented shape, for example, a circular or elliptical shape in the invention can prevent the crack problem during the following process. For example, in the following process for bonding wire using ultra-sonic waves to vibrate and compress the small wire on the bonding pad, the crack problem will not occur.

3. The specific structure of the bonding pad with a sharp-corner-prevented shape, for example, a circular or elliptical shape in the invention can also prevent crack problems upon the protective layer by the reason of difference of the coefficient of thermal expansion between the epoxy resin and the wafer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bonding pad structure, adaptive to a semiconductor device, the bonding pad structure being electrically coupled to a signal connection point of the semiconductor device, the bonding pad structure comprising:
a circular-shaped bonding pad; and
a dielectric layer, located between the bonding pad and the signal connection point, wherein a plural of plugs are formed in the dielectric layer and the plugs are used for electrically coupling the signal connection point and the bonding pad.

2. The structure claimed as claim 1, wherein the plugs of the dielectric layer are distributed evenly under the circular-shaped bonding pad in the dielectric layer.

3. The structure claimed as claim 1, wherein the plugs of the dielectric layer are distributed along and under the board of the circular-shaped bonding pad in the dielectric layer.

4. The structure claimed as claim 1, wherein the plugs of the dielectric layer are distributed under a center portion of the circular-shaped bonding pad in the dielectric layer.

5. The structure claimed as claim 1, wherein the plugs of the dielectric layer are distributed in a cross-shape under the circular-bonding pad in the dielectric layer.

6. The structure claimed as claim 1, wherein the material of the circular-shaped bonding pad is Aluminum (Al).

7. The structure claimed as claim 1, the semiconductor device further comprising a protective layer covering the bonding pad structure, wherein the circular-shaped bonding pad is exposed.

8. A bonding pad structure, adaptive to a semiconductor device, the bonding pad structure being electrically coupled to a signal connection point of the semiconductor device, the bonding pad structure comprising:
a elliptical-shaped bonding pad; and
a dielectric layer, located between the bonding pad and the signal connection point, wherein a plural of plugs are formed in the dielectric layer and the plugs are used for electrically coupling the signal connection point and the bonding pad.

9. The structure claimed as claim 8, wherein the plugs of the dielectric layer are distributed evenly under the elliptical-shaped bonding pad in the dielectric layer.

10. The structure claimed as claim 8, wherein the plugs of the dielectric layer are distributed along and under the board of the elliptical-shaped bonding pad in the dielectric layer.

11. The structure claimed as claim 8, wherein the plugs of the dielectric layer are distributed under a center portion of the elliptical-bonding pad in the dielectric layer.

12. The structure claimed as claim 8, wherein the plugs of the dielectric layer are distributed in a cross-shape under the elliptical-bonding pad in the dielectric layer.

13. The structure claimed as claim 8, wherein the material of the elliptical-bonding pad is Aluminum (Al).

14. The structure claimed as claim 8, the semiconductor device further comprising a protective layer covering the bonding pad structure, wherein the elliptical-shaped bonding pad is exposed.
